(19) United States
(12) Patent Application Publication
(10) Pub. No.: US 2015/0129292 A1
(43) Pub. Date: May 14, 2015

(54) PROCESS FOR PRODUCING A PRINTED CIRCUIT BOARD

(71) Applicant: THALES, Neuilly-sur Seine (FR)

(72) Inventors: Bernard Ledain, Sevres (FR); Dominique Henriot, Clamart (FR); Philippe Kertesz, Reeil Malmaison (FR)

(21) Appl. No.: 14/365,070

(22) PCT Filed: Dec. 11, 2012
(86) PCT No.: PCT/EP12/75105

§ 371 Date: Jun. 12, 2014

(30) Foreign Application Priority Data
Dec. 13, 2011 (FR) 11/03824

(51) Int. Cl. H05K 3/46; H05K 1/09; H05K 1/11; H05K 1/03

(52) U.S. Cl. CPC H05K 3/4623; H05K 1/0313; H05K 1/09; H05K 1/115; H05K 2201/0129; H05K 2201/041
USPC 174/258; 29/829

(57) ABSTRACT

A process is provided for producing a printed circuit board comprising at least two elementary circuit boards drilled with metallized holes the mouth of which is covered with a first metal, and at least one first intermediate layer, made of a compressible material, drilled with holes facing the elementary circuit boards and the mouth of which is covered with a second metal, which layer is placed between the two elementary circuit boards and soldered to each of the circuits by thermodiffusion of two metals forming an alloy at a formation temperature of the alloy. At least two second intermediate layers, the second layers not covering the first and second metal, being thermoplastics and having a melting point above the formation temperature of the alloy, are placed between the first intermediate layer and the elementary circuit boards.

The invention relates to the field of printed circuit boards, and more particularly to the mode of connection between various elementary circuit boards.

Each elementary metallized circuit board forms a portion of the printed circuit board. Conventionally, metallized holes passing through the elementary circuit boards are produced so as to guarantee electrical contact between the various elementary circuit boards. Preferably, the holes are only drilled between the elementary circuit boards to be connected. For example, for a printed circuit board comprising five elementary circuit boards, if only the third and the fifth circuit board must be connected, only the third, fourth and fifth circuit boards are perforated before being stacked to form a printed circuit board.

It is known to use an intermediate layer preimpregnated with an adhesive substance to adhesively bond the various elementary metallized circuit boards together. Each intermediate layer must also be perforated, facing the metallized holes to be electrically connected, with a larger diameter in order to take flow of the adhesive substance into account; in other words, the diameter of the through-holes in the intermediate layers must take into account the fact that deformation of the adhesive material could obstruct some of the hole. With the increase in the number of connections to be made, each intermediate layer is perforated with a multitude of very closely spaced holes, thereby making it very difficult to handle and limiting the possible density of connections.

A partial solution was provided by European patent EP 2 205 053.

This document describes the production of a printed circuit board comprising at least two superposed elementary circuit boards that are metallized on their two faces and at least one intermediate layer placed between said circuit boards. The intermediate layer comprises a thermoplastic material that is insensitive to chemical elements. With this type of intermediate layer, there is no risk of the thermoplastic material flowing.

The process for producing the printed circuit board according to document EP 2 205 053 may thus be summarized as follows. A first step consists in creating facing perforations in said elementary circuit boards and in the intermediate layer in order to connect said circuit boards together. A second step consists in lining the interior of the holes passing through the elementary circuit boards and the intermediate layer with a metal surface. A third step consists in covering the opening of the holes in the elementary circuit boards to be connected with a first metal, and the opening of the holes in the intermediate layer with a second metal. The first and second metal are the constituents of an alloy. After stacking, a fourth step consists in applying pressure so as to solder the metal surfaces that cover the openings of the holes in the elementary circuit boards with the metal surfaces that cover the openings of the holes in the intermediate layer. The solder is achieved by diffusion of the metals that then form an alloy.

One of the drawbacks of the embodiment provided in document EP 2 205 053 is that it runs into problems with mechanical tolerances. Specifically, the height of the metallized surfaces that cover the opening of the holes is greater than the height of the rest of the elementary circuit board. In order to remove these height differences, the pressure applied to the stack must be increased. The increase in the pressure applied prevents presses that are standard in the field of printed circuit boards from being used, and this type of board from being manufactured on an industrial scale.

One aim of the invention is to compensate for these height differences without increasing the pressure used to assemble the device.

According to one aspect of the invention, a process is provided for producing a printed circuit board comprising at least two elementary circuit boards drilled with metallized holes the mouth of which is covered with a first metal, and at least one first intermediate layer, made of a compressible material, drilled with holes facing the elementary circuit boards and the mouth of which is covered with a second metal, which layer is placed between the two elementary circuit boards and soldered to each of the circuits by thermodiffusion of the two metals forming an alloy at a formation temperature of the alloy, characterized in that at least two second intermediate layers, the second intermediate layers not covering the first and second metal, being thermoplastics and having a melting point above the formation temperature of the alloy, are placed between the first intermediate layer and said elementary circuit boards.

Adding at least two second intermediate thermoplastic layers having a melting point above the formation temperature of the alloy by thermodiffusion allows problems with mechanical tolerances to be limited and assembly pressures that are standard in the printed circuit board industry to once more be employed.

The invention will be better understood on studying a few embodiments described by way of completely nonlimiting examples, and illustrated by the appended drawings in which:

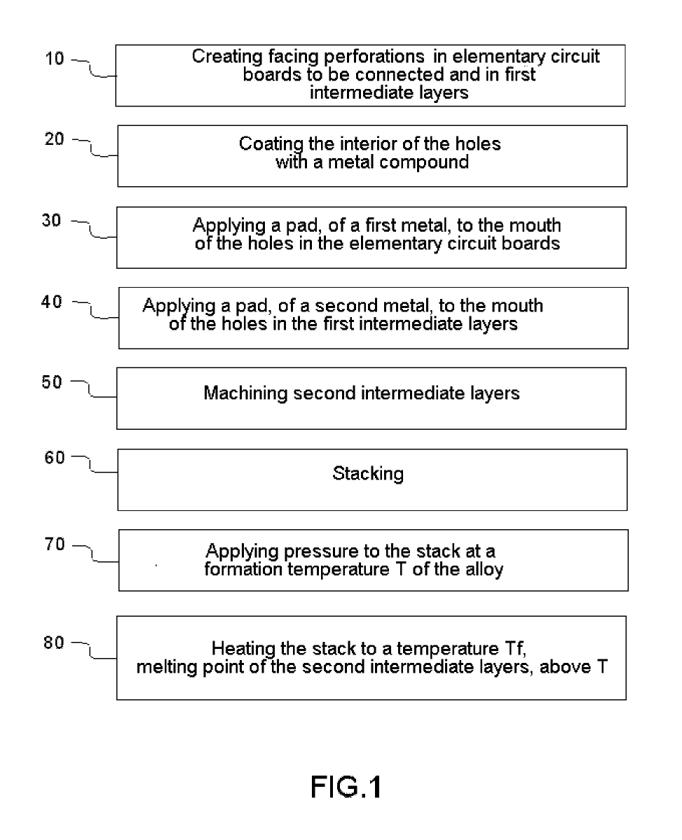

FIG. 1 illustrates a method of implementing a process for producing a printed circuit board according to one aspect of the invention;

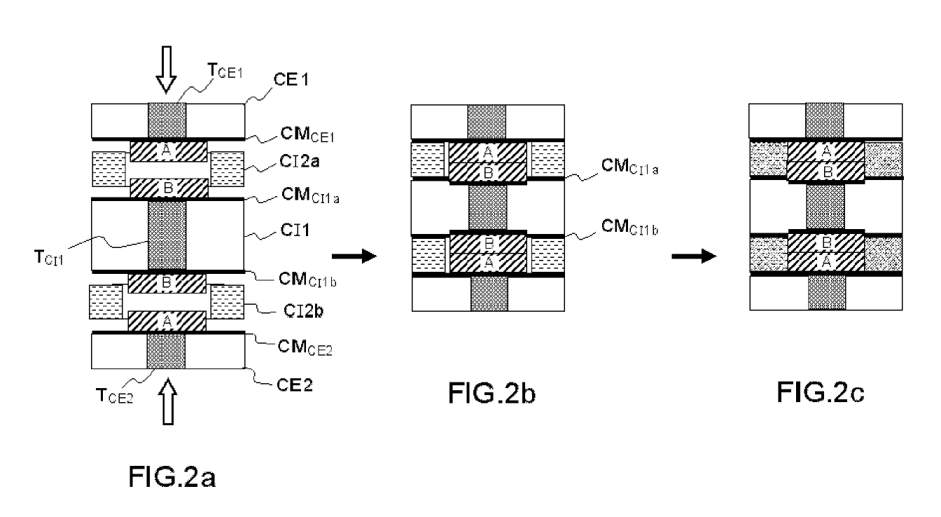

FIG. 2a shows a stack of the various constituent elements of a printed circuit board, according to one aspect of the invention;

FIG. 2b shows the stack of the various constituent elements of a printed circuit board in a press at a formation temperature T of the alloy, according to one aspect of the invention; and

FIG. 2c shows the stack of the various constituent elements of a printed circuit board in a press at a melting point Tf of the material of the second intermediate layers, according to one aspect of the invention.

FIG. 1 succinctly summarizes the process for producing a printed circuit board, according to the invention.

For example, a printed circuit board comprising at least two elementary circuit boards, at least one first intermediate layer and at least two second intermediate layers. Of course, this example is completely nonlimiting.

A first step 10 comprises drilling facing holes T_{CE1}, T_{CE2} in the elementary circuit boards CE1, CE2 to be connected. Advantageously, the elementary circuit boards CE1, CE2 may be composed of “RO 4003” (registered trademark), for example, and are covered, on at least one of their faces, with a metallization layer CM, preferably a layer containing copper.

This step also comprises drilling a first intermediate layer that is placed between the elementary circuit boards CE1, CE2 to be connected. The holes T_{CI1} formed are located facing the holes T_{CE1}, T_{CE2} in the elementary circuit boards CE1, CE2 to be connected. The first intermediate layer CI1 may be made of “RT Duroid 6002” (registered trademark), for example, and is covered with a metallization layer CM_{CI1a}, preferably a layer containing copper.

A step 20 comprises covering, with a metal compound, the inside of the holes formed in the elementary circuit boards CE1, CE2 and the first intermediate layer CI1. In other words, the interior of the holes is metallized in order to make them conductive, thereby allowing the elementary circuit boards CE1, CE2 to be electrically connected.

A step 30 comprises applying a first metal pad A to the mouth of the holes T_{CE1}, T_{CE2} drilled through the elementary circuit boards CE1, CE2. The first metal A is a constituent of a binary alloy AxBy created by thermodiffusion at a formation temperature T of the alloy.

Likewise, a step 40 comprises applying a second metal pad B to the mouth of the holes T_{CI1} drilled through the first intermediate layers CI1. The second metal B is a constituent of a binary alloy AxBy created by thermodiffusion at a formation temperature T of the alloy.

Advantageously, the composition of the alloy comprises silver and tin, indium and tin, or gold and tin, thereby allowing a formation temperature T that is clearly higher than the melting point of at least one of the constituents of the alloy, in this case tin, to be obtained for the alloy forming the electrical connections. The melting point of said alloy must be higher than the melting point of the solder used for the electrical connections of the electronic components mounted on the elementary circuit boards CE1, CE2.

A step 50 comprises machining the second intermediate layers CI2a, CI2b that do not cover the first and second metal. The second layers are made of thermoplastic and have a melting point Tf above the formation temperature T of the alloy. The second intermediate layers CI2a, CI2b are machined in order to guarantee sufficient clearance of the metal pads A and B to be joined by soldering. The thickness of the second intermediate layers CI2a, CI2b is slightly smaller, advantageously by 20 μm, than the sum of the thicknesses of the metallization layers CM_{CE1} of one of the elementary circuit boards CE1, of one of the metallization layers CM_{CI2a} of a first intermediate layer CI1 and of the metal pads A and B.

A step 60 comprises stacking the elementary circuit boards CE1, CE2, the first intermediate layers CI1 and the second intermediate layers CI2a, CI2b that make it possible to limit indentation of the compressible material CI1 due to height differences of the metallization layers.

A step 70 comprises applying pressure P, conventionally 20 bars, at a formation temperature T of the alloy, typically 235° C. for a tin/silver or gold/tin alloy. The temperature T applied allows the metal pads to be soldered by thermodiffusion. The constituent metals A and B of the pads diffuse to form the alloy AxBy. The pressure exerted compresses the first intermediate layers CI1 until they butt against the material of the second intermediate layers CI2a, CI2b, which is still stiff at this temperature. The use of a thickness of the second intermediate layers CI2a, CI2b smaller by 20 μm than the sum of the thicknesses of the metallization layers of one of the elementary circuit boards, of one of the two metallization layers of a first intermediate layer and of the metal pads A and B, makes it possible to emboss the first intermediate layer CI1, by about 20 μm per face, thereby making it possible to compensate for the thickness of the metallization layer under a metal pad.

A step 80 comprises heating the material of the second intermediate layers CI2a, CI2b to a melting point Tf, typically 290° C. for liquid-crystal polymers (LCP), while maintaining the pressure, typically 20 bars. At this temperature, the material of the second intermediate layers CI2a, CI2b melts and flows so as to fill available spaces and to adhesively bond the printed circuit boards CE1 and CE2 and the intermediate layer CI1.

FIGS. 2a, 2b and 2c illustrate the following steps of the process for producing a printed circuit board, according to the invention:

FIG. 2a shows a stack comprising two elementary circuit boards CE1 and CE2, for example made of “RO 4003” (registered trademark), a first intermediate layer CI1, for example made of “RT Duroid 6002” (registered trademark), which is placed between the two elementary circuit boards CE1 and CE2 to be connected, and two second intermediate layers CI2a and CI2b, for example made of LCP and of melting point Tf.

The two elementary circuit boards CE1 and CE2 are covered on at least one of their faces with a metallization layer CM_{CE1} and CM_{CE2}, advantageously a copper layer. Said circuit boards CE1 and CE2 are perforated with facing holes T_{CE1} and T_{CE2}, allowing said circuit boards to be connected together. The walls of said holes T_{CE1} and T_{CE2} are lined with a metal layer (not shown in the figure).

The first intermediate layer CI1 is covered with a metallization layer CM_{CI1a} and CM_{CI1b} on its two faces, advantageously a layer containing copper. The first intermediate layer CI1 is drilled with a hole T_{CI1} facing the holes T_{CE1} and T_{CE2} drilled through the elementary circuit boards CE1 and CE2. In the same way as for said holes T_{CE1} and T_{CE2}, the walls of the hole T_{CI1} are lined with a metallization layer (not shown in the figures).

The mouths of the holes T_{CE1} and T_{CE2}, which holes T_{CE1} and T_{CE2} are located facing and pass through the elementary circuit boards CE1 and CE2, are covered with a pad made of a first metal A, and the mouths of the hole T_{CI1} are covered with a pad made of a second metal B.

The metals A and B are the constituents of an alloy AxBy formed by thermodiffusion at the temperature T. Advantageously, the composition of the alloy comprises tin and silver, tin and indium, or gold and tin.

The second intermediate layers CI2a and CI2b are placed so as to compensate for height differences of the metallization layers and to limit the deformation of the compressible material M2 of the layer CI1 between the metal pads and the rest of the surface of the elementary circuit board or of the first intermediate layer, in order to guarantee an intimate connection of the assembly. The thickness of the second intermediate layers CI2a is, for example, smaller, preferably by 20 μm, than the sum of the thicknesses of one of the two metallization layers of the first intermediate layer CM_{CI1a}, of the metallization layer of the elementary circuit board CM_{CE1} and of the metal pads A and B.

FIG. 2b shows the stack in FIG. 2a in a press at constant temperature. The pressure, typically 20 bars, is applied at the formation temperature T of the alloy, for example 235° C. for a tin/silver or gold/tin alloy. The metals A and B diffuse to form the alloy AxBy, thus creating an electrical connection between the metallized holes T_{CE1}, T_{CE2} and T_{CI1}.

The pressure exerted compresses the first intermediate layer CI1 until it butts against the material of the second intermediate layers CI2a and CI2b, which is still stiff at the formation temperature T of the alloy. On account of the thickness chosen for the second intermediate layers, the embossing of the first intermediate layer has the advantage of compensating for the height difference due to the metallization layer CM_{CE1} of the elementary circuit board CE1 under the metal pad A.

FIG. 2c shows the stack shown in FIG. 2b after it has been heated to the melting point Tf of the material of the second intermediate layers CI2a and CI2b. At the melting point of the second intermediate layers CI2a and CI2b, the material forming these layers melts and flows to fill available spaces, in order to adhesively bond the circuit boards CE1 and CE2 of the intermediate layer CI1 and to compensate for height differences.

The production of a printed circuit board, according to the invention, allows height differences inside printed circuit boards to be compensated for, and thus presses that are standard in the printed circuit board industry to be used for their manufacture.

1. A process for producing a printed circuit board comprising at least two elementary circuit boards drilled with metallized holes the mouth of which is covered with a first metal, and at least one first intermediate layer, made of a compressible material, drilled with holes facing the elementary circuit boards and the mouth of which is covered with a second metal, which layer is placed between the two elementary circuit boards (CE1, CE2) and soldered to each of the circuits by thermodiffusion of the two metals forming an alloy at a formation temperature of the alloy, the process comprising: at least two second intermediate layers, the second intermediate layers not covering the first and second metal, being thermoplastics and having a melting point above the formation temperature ) of the alloy, are placed between the first intermediate layer and said elementary circuit boards.

2. The process as claimed in claim 1, comprising the following steps:
perforating the elementary circuit boards and the first intermediate layer in order to create facing holes in order to electrically connect the elementary circuit boards;
coating the holes formed in the elementary circuit boards and the first intermediate layer with a metal surface;
covering the orifice of the holes formed in the elementary circuit boards with a pad made of one of the metals of a binary alloy;
covering the orifice of the holes formed in the first intermediate layer with a pad made of the second metal of the binary alloy;
machining second intermediate layers in order to guarantee that the metal pads are not covered by said second intermediate layers; and
stacking the elementary circuit boards and intermediate layers.

3. The process as claimed in claim 2, comprising a step of applying pressure to the stack at a temperature corresponding to the formation temperature of the alloy, until the material forming the two intermediate layers, which material is still stiff at the temperature is butted against.

4. The process as claimed in claim 3, comprising a step of heating the stack to a melting point of the second intermediate layers.

5. A printed circuit board comprising at least two elementary circuit boards drilled with metallized holes the mouth of which is covered with a first metal, and at least one first intermediate layer, made of a compressible material, drilled with holes facing the elementary circuit boards and the mouth of which is covered with a second metal, which layer is placed between the two elementary circuit boards and soldered to each of the circuits by thermodiffusion of the two metals forming an alloy at a formation temperature of the alloy, wherein at least two second intermediate layers, the second intermediate layers being thermoplastics and having a melting point above the formation temperature of the alloy, are placed between the first intermediate layer and said elementary circuit boards.
